(19) United States
(12) Patent Application Publication
(10) Pub. No.: US 2015/0353345 A1
(43) Pub. Date: Dec. 10, 2015

(54) Vertical Hybrid Integrated MEMS ASIC Component Having A Stress Decoupling Structure

(71) Applicant: Robert Bosch GmbH, Stuttgart (DE)

(72) Inventors: Friedjof HEUCK, Stuttgart (DE); Ralf REICHENBACH, Esslingen (DE); Daniel Christoph MEISEL, Reutlingen (DE); Lars TEBJE, Reutlingen (DE); Mirko HATTASS, Stuttgart (DE); Jochen REINMUTH, Reutlingen (DE); Torsten KRAMER, Wannweil (DE); Johannes CLASSEN, Reutlingen (DE); Reinhard NEUL, Stuttgart (DE); Antoine PUYGRANIER, Reutlingen (DE)

(21) Appl. No.: 14/731,695

(22) Filed: Jun. 5, 2015

(30) Foreign Application Priority Data
Jun. 6, 2014 (DE) 10 2014 210 934.5

(51) Int. Cl. B81B 7/00

(52) U.S. Cl. CPC B81B 7/0016

(57) ABSTRACT

Method for on-chip stress decoupling to reduce stresses in a vertical hybrid integrated component including MEMS and ASIC elements and to mechanical decoupling of the MEMS structure. The MEMS/ASIC elements are mounted above each other via at least one connection layer and form a chip stack. On the assembly side, at least one connection area is formed for the second level assembly and for external electrical contacting of the component on a component support. At least one flexible stress decoupling structure is formed in one element surface between the assembly side and the MEMS layered structure including the stress-sensitive MEMS structure, in at least one connection area to the adjacent element component of the chip stack or to the component support, the stress decoupling structure being configured so that the connection material does not penetrate into the stress decoupling structure and flexibility of the stress decoupling structure is ensured.

### FIELD OF THE INVENTION

The present invention relates to a vertical hybrid integrated component, which at least includes a MEMS element and an ASIC element. The MEMS element is equipped with at least one deflectable structural element, which is implemented in a layered structure on a MEMS substrate. The ASIC element includes circuit functions, which are integrated into an ASIC substrate, and a layered structure on the ASIC substrate including at least one wiring level for the circuit functions. The individual element components of the component are each mounted one above the other via at least one connection layer and form a chip stack. On the assembly side of the component, at least one connection area is formed for the 2nd level assembly and for external electrical contacting of the component on a component support.

### BACKGROUND INFORMATION

In practice, the component concept under discussion here is frequently used in implementing sensor components having a MEMS sensor function, for example, for detecting accelerations, rotation rates, magnetic fields, or even pressures. These measured variables are converted into electrical signals with the aid of the MEMS element and are processed and evaluated with the aid of the ASIC circuit functions. Such components may be used for the most varied applications, for example, in the automotive and consumer segment. In the process, particular emphasis is placed on component miniaturization including high function integration. Vertical hybrid integrated components prove to be particularly advantageous in this respect, since repackaging of the chips is omitted in this case. Instead, the chip stack is mounted directly on an application circuit board as a so-called chip-scale package as part of the 2nd level assembly.

However, this direct assembly has the consequence that deformations of the component support are very directly coupled into the MEMS element and the MEMS structure. Deformations of the application circuit board may occur during aging of the device; however, they may also be attributable to temperature and/or pressure fluctuations, are induced by moisture or are assembly-related. In any case, they generally result in mechanical stresses in the component structure, which may severely impair the MEMS function. In sensor components, this may result in undesirable and undefined sensor behavior. Thus, for example, the sensitivity may change or a drift in the sensor signal may occur.

In practice, the component support and components are made independent of one another and they are usually also produced by different manufacturers. Thus, during the production of component supports, no measures are generally taken for reducing mechanical stresses which are transferred to a vertical hybrid integrated component in connection with assembly.

### SUMMARY OF THE INVENTION

The present invention describes measures for an on-chip stress decoupling which contribute in a simple way and reliably to reducing assembly-related mechanical stresses in the structure of a vertical hybrid integrated component of the type mentioned at the outset and in particular to the mechanical decoupling of the MEMS structure.

According to the present invention, this is achieved in that at least one flexible stress decoupling structure is formed in at least one element surface between the assembly side of the component and the MEMS layered structure having the deflectable structural element, specifically in at least one connection area to the adjacent element component of the chip stack or to the component support. This stress decoupling structure is configured in such a way that the connection material used for the particular connection does not penetrate into the stress decoupling structure and the flexibility of the stress decoupling structure is ensured.

According to the present invention, it has been found that mechanical stresses in the component support are initially coupled into the structure of the component via the mechanical and electrical connections of the 2nd level assembly. Depending on the position of the MEMS element within the chip stack, these mechanical stresses are also transferred via the connections between the individual element components of the chip stack to the MEMS element and to the stress-sensitive MEMS structure. Based on this, it is provided to implement in a targeted manner stress decoupling structures in certain connection areas of the component, in order to reduce assembly-related mechanical stresses in these areas of the component structure in a targeted manner. This is intended to achieve that the mechanical stresses do not propagate to the stress-sensitive MEMS structure within the chip stack. In this approach, the stress decoupling is obtained in a vertical hybrid integrated component exclusively via a suitable surface structuring of individual element components. To ensure the flexibility and consequently the function of the stress decoupling structure, the stress decoupling structure must be configured in such a way that the particular connection material is unable to penetrate into the stress decoupling structure and impair its flexibility, but instead remains essentially on the element surface.

The flexible stress decoupling structures of a vertical hybrid integrated component according to the present invention are used for the mechanical decoupling between the connection area including the connection material and the rest of the element. An improved mechanical decoupling in the lateral direction, i.e., within the element level, also makes it possible to improve the compensation for deformations of the component support. A vertical mechanical decoupling plays a rather minor role in this case. At the same time, the stress decoupling structures must, however, be mechanically stable enough that they pull through the 1st and 2nd level assembly without damage. Moreover, the stress decoupling structures should have available a sufficiently large surface area for applying the particular connection material. These requirements may be satisfied basically using entirely different structural elements.

With respect to effectiveness but also simple production, stress decoupling structures in the form of a diaphragm structure, a trench-web structure, a comb structure and/or a hole array in the element surface prove to be particularly advantageous. All these structures may be produced in the element surface in a simple manner using standard methods of surface micromechanics.

In the case of diaphragm structures, the entire diaphragm surface is available for applying connection material. The diaphragm structure may be completely closed. In this case, the connection material is unable to penetrate into the cavity under the diaphragm. However, the diaphragm structure may also include openings in the element surface if the outer diaphragm edge is connected to the surrounding substrate via a spring structure.

In the case of trench-web structures, comb structures and hole arrays, parts of the structure are connected vertically, i.e., not completely undercut. Via the structure layout including these connection points, it is possible to vary and optimize the stiffness anisotropy of the structure. It is thus possible in a simple manner to implement stress decoupling structures, which are vertically sufficiently stiff to apply and fuse solder balls or another connection material, and nonetheless ensure a high lateral mechanical decoupling of the connection areas.

In the case of open stress decoupling structures, the size of the openings in the element surface is advantageously selected in such a way that the connection material is unable to penetrate into the stress decoupling structure due to its surface tension.

Combinations of a diaphragm structure with an open structure, such as a trench-web structure or a comb structure, are also advantageous. This makes it possible to provide a relatively large surface area for applying the connection material. On the other hand, the stiffness anisotropy of such structures may be set in a targeted manner via the layout.

Basically, the chip stack of the vertical hybrid integrated component according to the present invention may include additional element components in addition to the MEMS element and the ASIC element, for example, additional MEMS and ASIC elements or a cap wafer for the MEMS function.

In one specific component variant, the ASIC element is mounted on the front-side layered structure of the MEMS element via at least one connection layer in at least one first connection area, so that at least the deflectable MEMS structural element is capped and its deflection capability is ensured. For this purpose, the ASIC element may be mounted on the MEMS layered structure either via its rear side or also face-to-face, i.e., via its front side. These structure variants are in particular suitable for micromechanical functions that do not require a media access, for example, acceleration measurement and rotation rate measurement. The component may be mounted on a component support either via the rear side of the MEMS element or via the surface of the ASIC element facing away from the MEMS element.

As already mentioned, at least one flexible stress decoupling structure is formed in at least one element surface between the assembly side of the component and the MEMS layered structure including the deflectable structural element.

In one specific embodiment, which in any case ensures a significant compensation for deformations of the component support, the assembly surface of the component has already been equipped with such stress decoupling structures.

Alternatively or in addition to this, however, stress decoupling structures may also be formed in the connection area between the MEMS element and an adjacent element, in particular in the layered structure of the MEMS element. This proves to be particularly advantageous if the MEMS element is not mounted on the component support directly, but instead via an additional element.

As has already been discussed above, there are various options for embodying and refining the present invention in an advantageous manner. For this purpose, reference is made, on the one hand, to the main subject matter described herein and its subordinate descriptions and, on the other hand, to the following description of multiple exemplary embodiments of the present invention based on the drawings.

### BRIEF DESCRIPTION OF THE DRAWINGS

FIG. 1 shows a schematic sectional representation of a vertical hybrid integrated component 100 for elucidating the system of stress decoupling structures according to the present invention.

FIGS. 2a, 2b and 2c each show a top view (above) and a section (below) through a stress decoupling structure according to the present invention.

### DETAILED DESCRIPTION

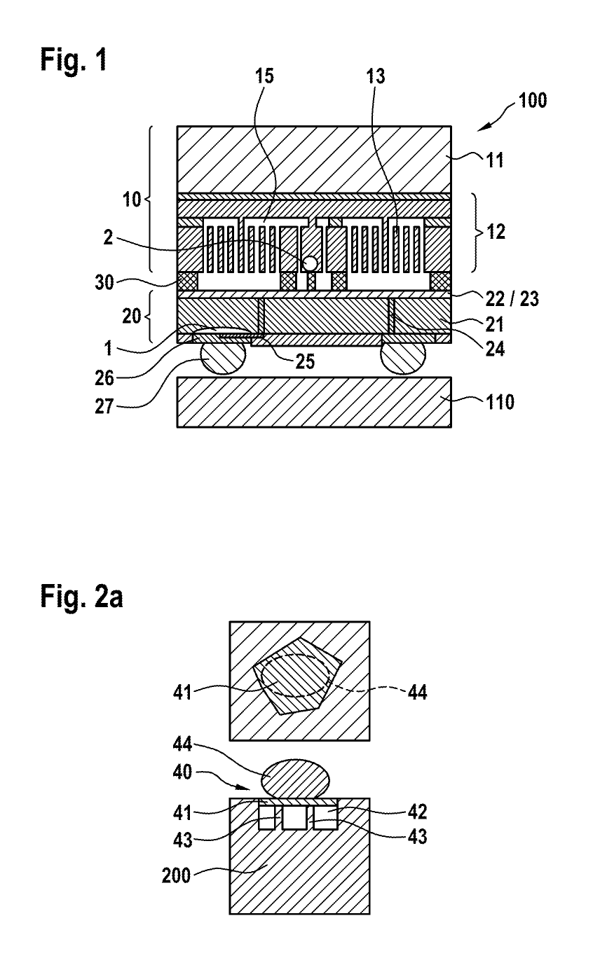

Vertical hybrid integrated component 100 illustrated in FIG. 1 includes a MEMS element 10 and an ASIC element 20. It is mounted on an application circuit board 110.

MEMS element 10 is an inertial sensor element. The accelerations are detected with the aid of a deflectable sensor structure 13, which together with a signal detection arrangement, which is not indicated here in greater detail, are implemented in a layered structure 12 on a MEMS substrate 11. To ensure that sensor structure 13 is movable, an intermediate space 15 is formed between sensor structure 13 and MEMS substrate 11.

ASIC element 20 includes electrical circuit components 23, which are integrated into ASIC substrate 21. These are advantageously parts of a signal processing circuit for evaluating the sensor signals of MEMS element 10. A layered structure 22 including wiring levels for circuit functions 23 is located on ASIC substrate 21. These wiring levels, which are not indicated here in greater detail, are connected using vias 24 to a wiring level 25 on rear side 101 of ASIC substrate 21, terminal pads 26 for the 2nd level assembly and for external electrical contacting of component 100 being formed in the wiring level.

MEMS element 10 and ASIC element 20 are mounted one above the other and form a chip stack. For this purpose, the active side of MEMS chip 10, in which sensor structure 13 is formed, was connected to the active side of ASIC chip 20, on which circuit functions 23 are implemented by eutectic bonding. Connection layer 30 produced in this way is structured so that it forms a stand-off structure between MEMS layered structure 12 and ASIC element 20, which ensures the movability of sensor structure 13. Connection layer 30 is also structured in such a way that the mechanical connection between MEMS layered structure 12 and ASIC element 20 completely surrounds sensor structure 13 and the sensor structure is enclosed in a hermetically sealed way between MEMS substrate 11 and ASIC element 20. Via structured connection layer 30, sensor structure 13 was also connected electrically to ASIC element 20.

As already indicated, rear side 101 of ASIC element 20 functions in the exemplary embodiment shown here as an assembly side of component 100 for the 2nd level assembly. Terminal pads 26 form the connection areas for the mechanical fixing on application circuit board 110 and the external electrical contacting. These connections are implemented here with the aid of solder balls 27.

According to the present invention, at least one flexible stress decoupling structure should be formed in at least one element surface between assembly side 101 of component 100 and MEMS layered structure 12 having deflectable sensor structure 13, specifically in at least one connection area to the adjacent element component of the chip stack or to component support 110. Here, the stress decoupling structure should be configured in such a way that the connection material used for the particular connection does not penetrate into the stress decoupling structure and the flexibility of the stress decoupling structure is ensured.

FIG. 1 illustrates the places in the component structure where such a stress decoupling structure may be reasonably situated. In the exemplary embodiment described here, only assembly side 101 of component 100, i.e., the rear side of ASIC element 20, the active front side of ASIC element 20 and the active front side of MEMS element 10 may be considered for this. According to FIG. 1, stress decoupling structures are on the one hand provided in the rear side of ASIC element 20, specifically in the area of terminal pads 26 in position 1. The surface of these stress decoupling structures in assembly side 101 of component 100 are advantageously provided with a partially structured electrically conductive layer, in order to ensure the electrical coupling of solder balls 27 to vias 25 in ASIC element 20. On the other hand, according to FIG. 1, stress decoupling structures should be formed in MEMS layered structure 12, specifically in position 2 in the area of the connection of sensor structure 13 to MEMS substrate 11 on the one hand and to ASIC element 20 on the other. This stress decoupling structure may be produced advantageously in the same structuring process in which also sensor structure 13 is exposed. In comparison to this, a structuring of the active ASIC upper surface would be significantly more complex, since the micromechanical structuring processes are generally not compatible with a CMOS processing.

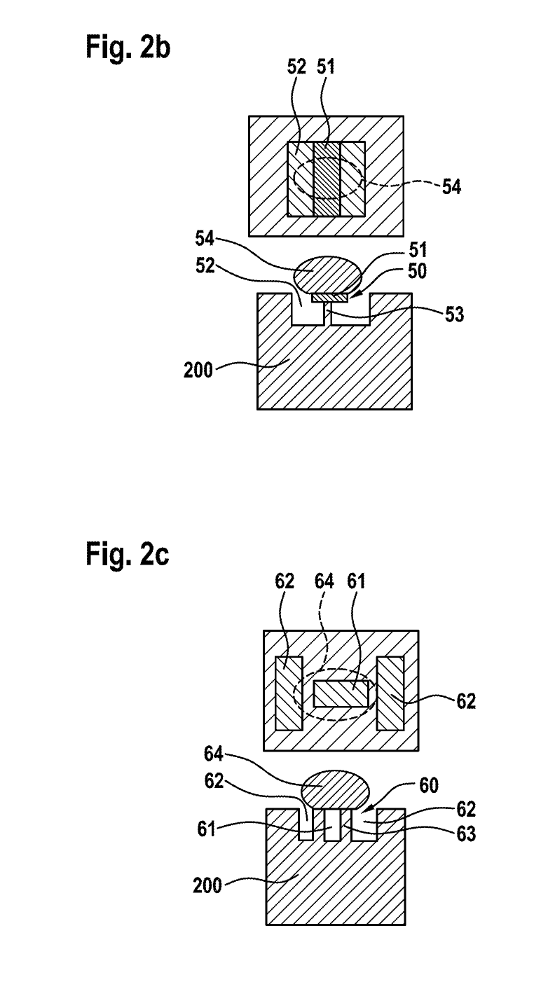

FIGS. 2a through 2c illustrate different implementation forms for a flexible stress decoupling structure, which may be implemented on positions 1 and/or 2 of the component structure shown in FIG. 1.

A stress decoupling structure in the form of a diaphragm structure 40 is shown in FIG. 2a. It includes a closed diaphragm 41 which is formed in the element surface, and its edge is connected circumferentially to surrounding substrate 200. Diaphragm 41 spans a cavity 42 in substrate 200 and may be connected to the cavity bottom via supporting points 43. Diaphragm 41 is used here as a support for solder ball 44, which is used as connection material for the 2nd level assembly. Since diaphragm 41 is closed, this connection material 44 is unable to penetrate into stress decoupling structure 40, i.e., into cavity 42 under diaphragm 41, which would lessen the flexibility of stress decoupling structure 40. The horizontal stiffness of stress decoupling structure 40 may be influenced and set in a simple and targeted manner using layout parameters, such as the size and shape of diaphragm 41 as well as the number, thickness and position of supporting points 43.

In contrast to stress decoupling structure 40 of FIG. 2a, stress decoupling structure 50 shown in FIG. 2b is an open trench structure 52 in the element surface. In the center area of trench structure 52, one or multiple supporting points 53 may be formed for a rectangular diaphragm segment 51, of which, however, only its face is connected to the adjacent substrate surface. Solder ball 54 for the 2nd level assembly is positioned here on diaphragm segment 51. The dimensions of trench opening 52 are selected in such a way that solder material 54 does not penetrate into trench structure 52 due to its surface tension. In this embodiment variant as well, the horizontal stiffness may be set simply via the layout parameters of stress decoupling structure 50.

The specific embodiment of a stress decoupling structure 60 shown in FIG. 2c is implemented in the form of a trench-web structure. Connection material 64 is in this case placed over a first trench opening 61 which, on at least two diametrically opposed sides, is only limited by wall webs 63 between trench opening 61 and additional trenches 62. Due to the surface tension of connection material 64, this remains only on the edge area of trench opening 61, i.e., in the area of the element surface, and also does not penetrate into trench structure 60 during the assembly process.

At this point, it should be noted that such trench-web structures may also be implemented in an array configuration.

All three flexible stress decoupling structures 40, 50 and 60 shown in FIGS. 2a through 2c may also be implemented in an array configuration. They may be produced in an element surface in a simple manner with the aid of conventional MEMS processes, i.e., in the rear side of the substrate or also in a layered structure on the front side of the substrate.

It is thus possible to produce diaphragm structures in the element surface with the aid of etched lattice structures, which are covered by a non-conforming deposition. However, diaphragms may also be produced, for example, by sacrificial layer etching or with the aid of porous silicon and its repositioning. Open diaphragm structures may be produced by structuring a closed diaphragm or also by anisotropic deep etching and subsequent lateral undercutting. Here, the vertical stiffness anisotropy may be set by the ratio of deep etching to undercutting. Finally, it should be noted that the stress decoupling structures described here may also extend across multiple layers of the element structure, in particular when they are implemented in the layered structure of the MEMS element.

1-5. (canceled)

6. A vertical hybrid integrated component, comprising:
a micro-electro-mechanical (MEMS) element having at least one deflectable structural element, which is implemented in a layered structure on a MEMS substrate; and
an application-specific-integrated-circuit (ASIC) element having circuit functions, which are integrated into an ASIC substrate, and having a layered structure on the ASIC substrate, which includes at least one wiring level for the circuit functions, wherein the MEMS element and the ASIC element of the component are each mounted one above the other via at least one connection layer and forming a chip stack and at least one connection area being formed on the assembly side of the component for the second level assembly and for external electrical contacting of the component on a component support; and
at least one flexible stress decoupling structure formed in at least one element surface between the assembly side of the component and the MEMS layered structure including the deflectable structural element, in at least one connection area to the adjacent element component of the chip stack or to the component support, the stress decoupling structure being configured so that the connection material used for the particular connection does not penetrate into the stress decoupling structure and the flexibility of the stress decoupling structure is ensured.

7. The component of claim 6, wherein the stress decoupling structure includes at least one of a hole array, a trench-web structure, a comb structure and a diaphragm structure in the element surface.

8. The component of claim 6, wherein the ASIC element is mounted on the front-side layered structure of the MEMS element via at least one connection layer in at least one first connection area, so that at least the deflectable structural element is capped and its deflection capability is ensured.

9. The component of claim 6, wherein at least one stress decoupling structure is implemented in the assembly surface of the component.

10. The component of claim 6, wherein at least one stress decoupling structure is implemented in the connection area between the MEMS element and an adjacent element.

11. The component of claim 6, wherein at least one stress decoupling structure is implemented in the assembly surface of the component, in particular in the rear side of the ASIC substrate or in the rear side of the MEMS substrate.

12. The component of claim 6, wherein at least one stress decoupling structure is implemented in the connection area between the MEMS element and an adjacent element, in particular in the layered structure of the MEMS element.
